(19) United States
(12) Patent Application Publication
(10) Pub. No.: US 2026/0019046 A1
(43) Pub. Date: Jan. 15, 2026

(54) POWER AMPLIFIER CIRCUIT

(71) Applicant: Murata Manufacturing Co., Ltd., Nagaokakyo-shi (JP)

(72) Inventor: Yuki Tanaka, Nagaokakyo-shi (JP)

(21) Appl. No.: 19/257,574

(22) Filed: Jul. 2, 2025

(30) Foreign Application Priority Data
Jul. 12, 2024 (JP) 2024-112670

(51) Int. Cl. H03F 1/30; H03F 3/21

(52) U.S. Cl. CPC H03F 1/30; H03F 3/21; H03F 2200/447

(57) ABSTRACT

A power amplifier circuit includes an amplifier that operates on power supplied from a first terminal; a first transistor having a collector or a drain, an emitter or a source, and a base or a gate; a first diode having an anode and a cathode, the anode being connected to the control terminal; a second diode having an anode and a cathode, the anode being connected to the cathode of the first diode, the cathode being connected to ground; a second transistor having a collector or a drain, a base or a gate, and an emitter or a source; and a constant-voltage generation circuit that supplies a constant voltage to the base or the gate of the second transistor.

### CROSS REFERENCE TO RELATED APPLICATION

This application claims priority from Japanese Patent Application No. 2024-112670, filed on Jul. 12, 2024. The content of these applications are incorporated herein by reference in its entirety.

### BACKGROUND OF THE DISCLOSURE

### 1. Field of the Disclosure

The present disclosure relates to a power amplifier circuit.

### 2. Description of the Related Art

Japanese Unexamined Patent Application Publication No. 11-330866 describes a power amplifier including a pair of diode-connected transistors connected between ground and the base of a driver transistor. In the power amplifier, a RF signal to be amplified is coupled to the input of a power transistor, and the amplified RF signal is acquired from the collector of the power transistor. The driver transistor that biases the power transistor for an appropriate operating point is also coupled to the input of the power transistor.

### BRIEF SUMMARY OF THE DISCLOSURE

In the power amplifier described in Japanese Unexamined Patent Application Publication No. 11-330866, the pair of diode-connected transistors follow a voltage drop in the base-emitter junction between the driver transistor and the power transistor. The following causes the base current of the power transistor to remain substantially constant and to remain stable at the operating point. However, in this configuration, the gain of the power transistor is compensated insufficiently on occasions when temperature is changed. Specifically, the gain of the power transistor is decreased at a temperature increase.

The present disclosure has been made under the circumstances as described above, and it is thus a possible benefit of the present disclosure to provide a power amplifier circuit enabled to appropriately compensate a change in the gain of the amplifier at a temperature increase.

A power amplifier circuit according to an aspect of the present disclosure includes: an amplifier that operates on power supplied from a first terminal; a first transistor having a collector or a drain, an emitter or a source, and a base or a gate, the collector or the drain being supplied with power from a second terminal, the emitter or the source supplying bias to the amplifier via a first resistance element, the base or the gate being connected to a control terminal; a first diode having an anode and a cathode, the anode being connected to the control terminal; a second diode having an anode and a cathode, the anode being connected to the cathode of the first diode, the cathode being connected to ground; a second transistor having a collector or a drain, a base or a gate, and an emitter or a source, the collector or the drain being connected to the first terminal with a second resistance element interposed between the first terminal and the collector or the drain, the emitter or the source being connected to the anode of the second diode; and a constant-voltage generation circuit that supplies a constant voltage to the base or the gate of the second transistor.

A power amplifier circuit according to another aspect of the present disclosure includes: an amplifier that operates on power supplied from a first terminal; a first transistor having a collector or a drain, an emitter or a source, and a base or a gate, the collector or the drain being supplied with power from a second terminal, the emitter or the source supplying bias to the amplifier via a first resistance element, the base or the gate being connected to a control terminal; a first diode having an anode and a cathode, the anode being connected to the control terminal; a second diode having an anode and a cathode, the anode being connected to the cathode of the first diode, the cathode being connected to ground; a fourth transistor having a collector or a drain, a base or a gate, and an emitter or a source, the collector or the drain being connected to the first terminal with a second resistance element interposed between the first terminal and the collector or the drain, the emitter or the source being connected to the anode of the second diode; and a voltage generation circuit that supplies the base or the gate of the fourth transistor with a voltage causing an on state of the fourth transistor and a voltage causing an off state of the fourth transistor, the voltage causing the on state being supplied when a control signal causing an on state of the amplifier is supplied from the control terminal, the voltage causing the off state being supplied when a control signal causing an off state of the amplifier is supplied from the control terminal.

According to the present disclosure, the power amplifier circuit enabled to appropriately compensate a change in the gain of the amplifier at a temperature increase may be provided.

### BRIEF DESCRIPTION OF THE SEVERAL VIEWS OF THE DRAWINGS

FIG. 1 is a circuit diagram of a power amplifier circuit 101;

FIG. 2 is a circuit diagram of a power amplifier circuit 102;

FIG. 3 is a circuit diagram of a power amplifier circuit 103;

FIG. 4 is a circuit diagram of a power amplifier circuit 104;

FIG. 5 is a circuit diagram of a power amplifier circuit 105;

FIG. 6 is a circuit diagram of a power amplifier circuit 901 that is a reference example;

FIG. 7 is a graph illustrating an example of the simulation results of temperature changes in collector current Ic1 in the power amplifier circuit 105 and diode current Idr in the power amplifier circuit 901;

FIG. 8 is a graph illustrating an example of the simulation results of temperature changes in bias current Ib in the power amplifier circuit 105 and bias current Ibr in the power amplifier circuit 901;

FIG. 9 is a graph illustrating an example of the simulation results of frequency changes in the gain of an amplifier 56 in the power amplifier circuit 105;

FIG. 10 is a graph illustrating an example of the simulation results of frequency changes in the gain of the amplifier 56 in the power amplifier circuit 901; and

FIG. 11 is a circuit diagram of a power amplifier circuit 106.

### DETAILED DESCRIPTION OF THE DISCLOSURE

Hereinafter, embodiments of the present disclosure will be described in detail with reference to the drawings. The same components are denoted by the same reference numerals, and overlapping explanation is omitted as much as possible.

### First Embodiment

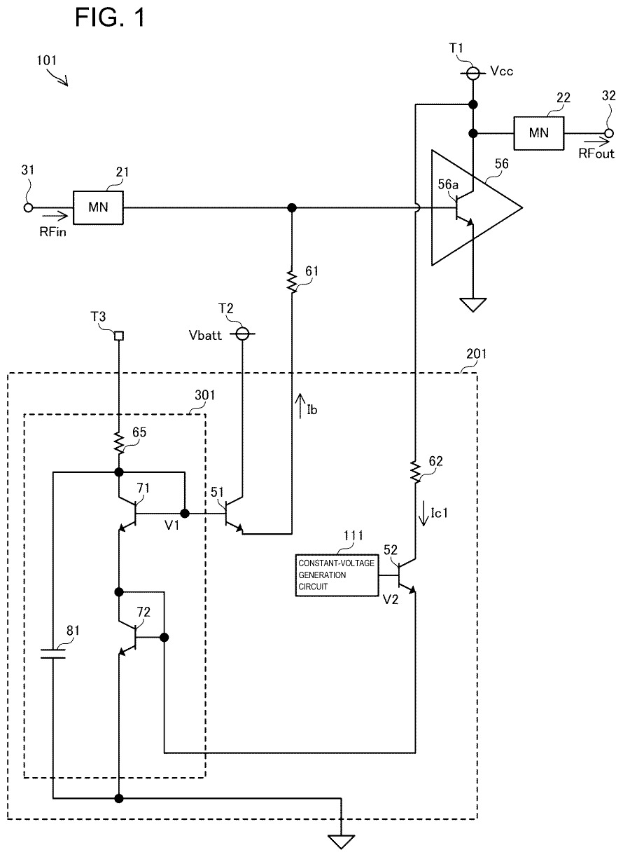

A power amplifier circuit 101 according to a first embodiment will be described. FIG. 1 is a circuit diagram of the power amplifier circuit 101. As illustrated in FIG. 1, the power amplifier circuit 101 includes matching circuits 21 and 22, an amplifier 56, a resistance element 61 (first resistance element), and a bias circuit 201.

The amplifier 56 includes an amplifying transistor 56a. The bias circuit 201 includes a bias supply transistor 51 (first transistor), a transistor 52 (second transistor), a resistance element 62 (second resistance element), a constant-voltage generation circuit 111, and a voltage applying circuit 301.

In this embodiment, each transistor is formed as a bipolar transistor such as a hetero-junction bipolar transistor (HBT). The transistor may be formed as another transistor such as a field effect transistor (metal-oxide-semiconductor field-effect transistor (MOSFET)). In this case, a base, a collector, and an emitter may be respectively read as a gate, a drain, and a source.

The matching circuit 21 in the power amplifier circuit 101 is provided between an input terminal 31 and the amplifier 56 and matches impedance between a circuit (not illustrated) provided in a prior stage of the input terminal 31 and the amplifier 56.

The amplifying transistor 56a in the amplifier 56 operates on a power supply voltage Vcc. The amplifying transistor 56a amplifies an input signal RFin supplied from the input terminal 31 via the matching circuit 21 and outputs an output signal RFout to an output terminal 32 via the matching circuit 22, the output signal RFout serving as an amplification signal.

The matching circuit 22 is provided between the amplifier 56 and the output terminal 32 and matches impedance between a circuit (not illustrated) provided in a subsequent stage of the output terminal 32 and the amplifier 56.

In detail, a voltage supply terminal T1 (first terminal) provides the power supply voltage Vcc for causing the amplifying transistor 56a to operate and is connected to the collector of the amplifying transistor 56a.

The amplifying transistor 56a has the collector connected to the output terminal 32 with the matching circuit 22 interposed therebetween, a base connected to the input terminal 31 with the matching circuit 21 interposed therebetween, and an emitter connected to ground.

The bias circuit 201 supplies bias current Ib to the base of the amplifying transistor 56a by using the bias supply transistor 51 that is emitter-follower connected to the base of the amplifying transistor 56a.

In detail, the bias supply transistor 51 has a collector connected to a voltage supply terminal T2 that supplies a battery voltage Vbat, a base, and an emitter connected to the base of the amplifying transistor 56a with the resistance element 61 interposed therebetween.

The voltage applying circuit 301 supplies bias with a voltage V1 to the base of the bias supply transistor 51. In this embodiment, the voltage applying circuit 301 includes a resistance element 65, transistors 71 (first diode) and 72 (second diode), and a capacitor 81.

A control terminal T3 supplies, for example, constant current as a control signal. The control terminal T3 is connected to the base of the bias supply transistor 51 with the resistance element 65 interposed therebetween.

The transistor 71 has a collector (anode) connected to the base of the bias supply transistor 51, a base connected to the collector (anode), and an emitter (cathode). Hereinafter, connection between the collector of a transistor and the base of a transistor is referred to as diode connection on occasions.

The transistor 72 is diode connected. The transistor 72 has a collector (anode) connected to the emitter of the transistor 71 and an emitter (cathode) connected to ground.

The capacitor 81 has a first end connected to the collector of the transistor 71 and a second end connected to ground. The capacitor 81 stabilizes a voltage at the collector of the transistor 71.

Each of the transistors 71 and 72 functions as a diode. Voltage drops in two respective diodes occur on a path between the collector of the transistor 71 and the emitter thereof and a path between the collector of the transistor 72 and the emitter thereof. That is, the voltage at the collector of the transistor 71 with respect to ground is the voltage V1 with a level corresponding to the voltage drops in the two diodes. The voltage V1 is applied to the base of the bias supply transistor 51.

The transistor 72 may be disposed to be thermally coupled to the amplifier 56. In detail, the transistor 72 and the amplifier 56 are provided close to each other. Alternatively, a configuration in which the transistor 72 and the amplifier 56 are formed on the same chip may be used. Alternatively, a configuration in which the transistor 72 and the amplifier 56 are mounted in or on the substrate as close to each other as possible may be used. With this configuration, in response to an increase in the temperature of the amplifier 56, heat flows from the amplifier 56 into the transistor 72, and the temperature of the transistor 72 becomes close to the temperature of the amplifier 56. In contrast, in response to a drop in the temperature of the amplifier 56, heat flows from the transistor 72 into the amplifier 56, and the temperature of the transistor 72 becomes close to the temperature of the amplifier 56.

The transistor 52 has a collector connected to the voltage supply terminal T1 with the resistance element 62 interposed therebetween, a base, and an emitter connected to the collector of the transistor 72.

The constant-voltage generation circuit 111 supplies a constant voltage V2 to the base of the transistor 52. The constant voltage V2 is substantially constant even if the temperature of the amplifier 56 or the temperature of the transistor 72 is changed.

### Effects

For example, if the temperature of the amplifier 56 is increased after the amplifier 56 transitions from an off state to an on state, the gain of the amplifier 56 is decreased.

In the power amplifier circuit 101, the temperature increase in the amplifier 56 also leads to a temperature increase in the transistor 72 thermally coupled to the amplifier 56, and thus a base-emitter voltage Vbe across the transistor 72 drops. The temperature increase in the transistor 72 is not limited to the temperature increase due to the temperature increase in the amplifier 56 and includes a case where the temperature of the transistor 72 or the entire power amplifier circuit 101 is increased due to the external environment.

Since the constant-voltage generation circuit 111 supplies the constant voltage V2 regardless of the temperature of the amplifier 56 or the transistor 72, the base-emitter voltage Vbe across the transistor 52 is increased. Collector current Ic1 of the transistor 52 is thereby increased.

The increase in collector current Ic1 leads to an increase in the base current of the transistor 72 and also an increase in current flowing to the transistors 71 and 72.

Since the bias supply transistor 51 is current mirror connected to the transistor 71, the increase in the current that flows to the transistor 71 leads to an increase in the bias current Ib supplied by the bias supply transistor 51 to the amplifier 56 and thus an increase in the gain of the amplifier 56.

In other words, the increase in the collector current Ic1 causes the base current of the transistor 72 to be increased and thus causes the base-emitter voltage Vbe across the transistor 72 and the base-emitter voltage Vbe across the transistor 71 to be increased.

That is, since the voltage V1 applied to the base of the bias supply transistor 51 is increased, the bias current Ib supplied by the bias supply transistor 51 to the amplifier 56 is increased, and thus the gain of the amplifier 56 is increased.

Even if the gain of the amplifier 56 is decreased due to the temperature increase, the bias current Ib supplied from the bias supply transistor 51 to the amplifier 56 is increased, and thus a decrease in the gain of the amplifier 56 may be prevented.

On the other hand, in a case of a temperature drop in the amplifier 56 and an increase in the gain of the amplifier 56, the collector current Ic1 in the transistor 52 is decreased, and the bias current Ib is also decreased. An increase in the gain of the amplifier 56 may thus be prevented. That is, a change in the gain of the amplifier 56 due to a temperature change may be prevented.

### Second Embodiment

A power amplifier circuit according to a second embodiment will be described. A power amplifier circuit 102 according to the second embodiment will be described. Description of matter common to the first embodiment is omitted in and after the second embodiment, and only different points are described. In particular, the same effects and operations of the same configuration are not referred to in each embodiment.

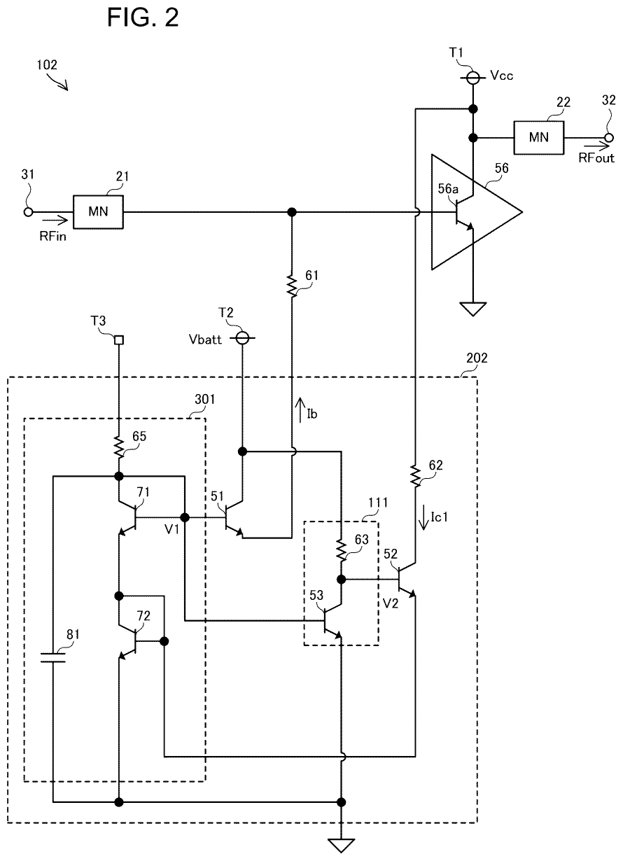

FIG. 2 is a circuit diagram of the power amplifier circuit 102. As illustrated in FIG. 2, the power amplifier circuit 102 is different from the power amplifier circuit 101 according to the first embodiment in that the constant-voltage generation circuit 111 is simplified.

As compared with the power amplifier circuit 101 illustrated in FIG. 1, the power amplifier circuit 102 includes a bias circuit 202 in place of the bias circuit 201. The constant-voltage generation circuit 111 in the bias circuit 202 includes a transistor 53 (third transistor) and a resistance element 63 (third resistance element).

The resistance element 63 has a first end connected to the voltage supply terminal T2 and a second end connected to the base of the transistor 52.

The transistor 53 has a collector connected to the second end of the resistance element 63, an emitter connected to ground, and a base connected to the base of the bias supply transistor 51.

As described above, with the simplified configuration having the one resistance element and the one transistor, a circuit that applies the constant voltage V2 to the base of the transistor 52 may be achieved.

In addition, with the configuration in which the base of the transistor 53 is connected to the control terminal T3 with the resistance element 65 interposed therebetween, the transistor 53 may be caused to transition to the off state when the current supplied from the control terminal T3 becomes off. Current that flows to ground from the voltage supply terminal T2 via the resistance element 63 and the transistor 53 may thereby be blocked when the amplifier 56 enters into the off state, and thus power consumption may be reduced.

### Third Embodiment

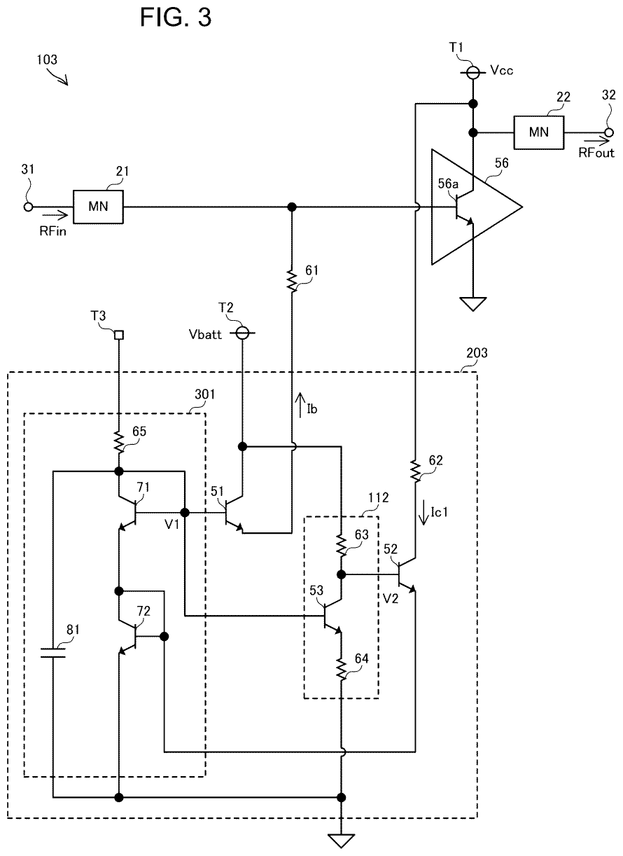

A power amplifier circuit according to a third embodiment will be described. FIG. 3 is a circuit diagram of a power amplifier circuit 103. As illustrated in FIG. 3, the power amplifier circuit 103 is different from the power amplifier circuit 102 according to the second embodiment in that the emitter of the transistor 53 is connected to ground with a resistance element 64 interposed therebetween.

As compared with the power amplifier circuit 102 illustrated in FIG. 2, the power amplifier circuit 103 includes a bias circuit 203 in place of the bias circuit 202. As compared with the bias circuit 202 illustrated in FIG. 2, the bias circuit 203 includes a constant-voltage generation circuit 112 in place of the constant-voltage generation circuit 111.

As compared with the constant-voltage generation circuit 111 illustrated in FIG. 2, the constant-voltage generation circuit 112 further includes the resistance element 64 (a fourth resistance element).

The resistance element 64 has a first end connected to the emitter of the transistor 53 and a second end connected to ground.

With the configuration as described above, the constant voltage V2 applied to the base of the transistor 52 may be appropriately controlled by appropriately setting the temperature characteristics of the transistor 53, the resistance value of the resistance element 63, and the resistance value of the resistance element 64. Specifically, for example, the constant voltage V2 at a high temperature may be slightly increased or decreased.

### Fourth Embodiment

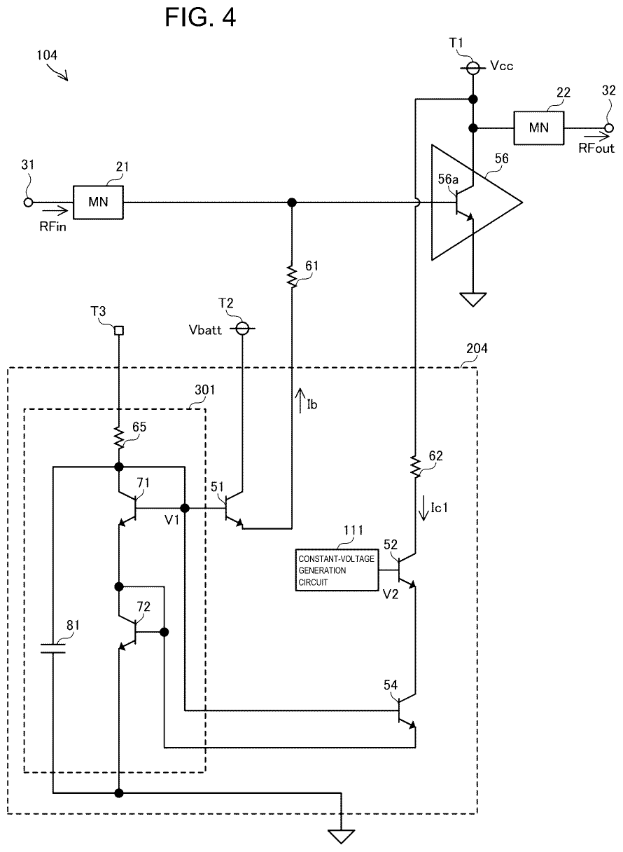

A power amplifier circuit according to a fourth embodiment will be described. FIG. 4 is a circuit diagram of a power amplifier circuit 104. As illustrated in FIG. 4, the power amplifier circuit 104 is different from the power amplifier circuit 101 according to the first embodiment in that the collector current Ic1 is prevented from serving as leakage current.

As compared with the power amplifier circuit 101 illustrated in FIG. 1, the power amplifier circuit 104 includes a bias circuit 204 in place of the bias circuit 201. As compared with the bias circuit 201 illustrated in FIG. 1, the bias circuit 204 further includes a transistor 54 (fourth transistor).

The transistor 54 has a collector connected to the emitter of the transistor 52, a base connected to the base of the bias supply transistor 51, and an emitter connected to the base of the transistor 72.

As described above, with the configuration in which the base of the transistor 54 is connected to the control terminal T3 with the resistance element 65 interposed therebetween, the transistor 54 may be caused to transition to the off state when the current supplied from the control terminal T3 becomes off. This enables current that flows from the voltage supply terminal T1 to ground via the resistance element 62, the transistor 52, the transistor 54, and the transistor 72 to stop when the amplifier 56 enters into the off state, and thus power consumption may be reduced.

### Fifth Embodiment

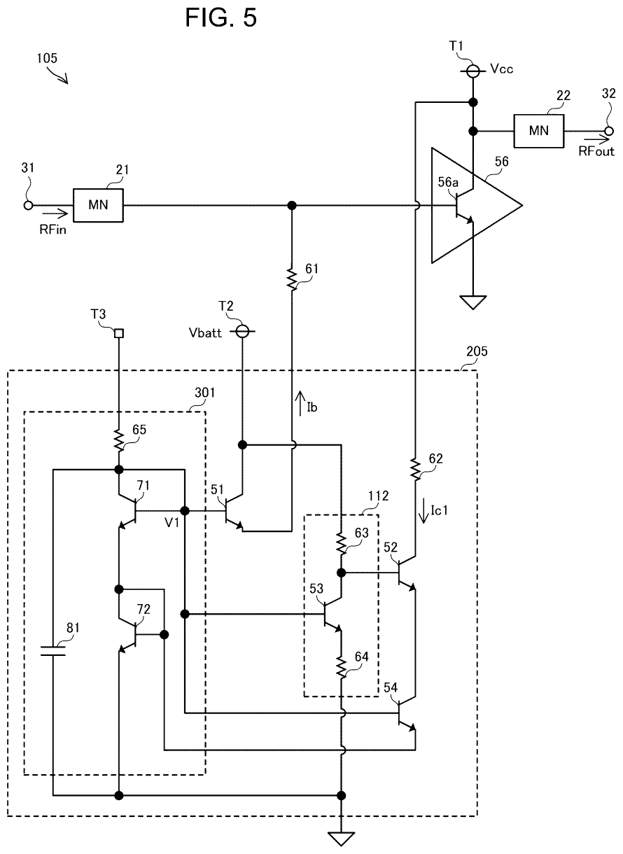

A power amplifier circuit according to a fifth embodiment will be described. FIG. 5 is a circuit diagram of a power amplifier circuit 105. As illustrated in FIG. 5, the power amplifier circuit 105 is different from the power amplifier circuit 104 according to the fourth embodiment in that the constant-voltage generation circuit 112 is simplified.

As compared with the power amplifier circuit 104 illustrated in FIG. 4, the power amplifier circuit 105 includes a bias circuit 205 in place of the bias circuit 204. As compared with the bias circuit 204 illustrated in FIG. 4, the bias circuit 205 includes the constant-voltage generation circuit 112 in place of the constant-voltage generation circuit 111. The constant-voltage generation circuit 112 is the same as the constant-voltage generation circuit 112 in the power amplifier circuit 103 (see FIG. 3).

### Simulation Results

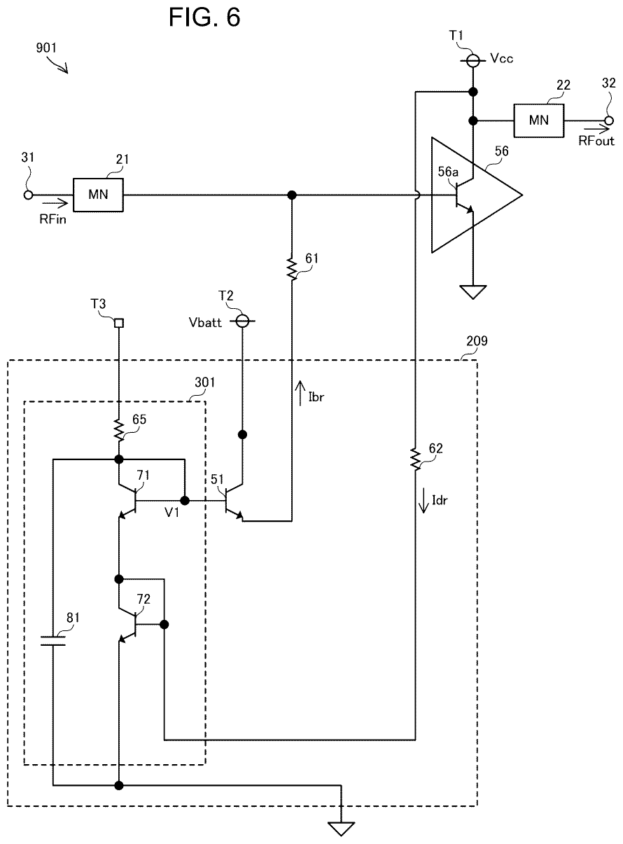

FIG. 6 is a circuit diagram that is a reference example of a power amplifier circuit 901. As compared with the power amplifier circuit 105 illustrated in FIG. 5, the power amplifier circuit 901 does not include the transistors 52 and 54 and the constant-voltage generation circuit 112.

In the power amplifier circuit 901, diode current Idr flows from the voltage supply terminal T1 to the base of the transistor 72 via the resistance element 62. The bias supply transistor 51 supplies bias current Ibr to the amplifier 56 via the resistance element 61.

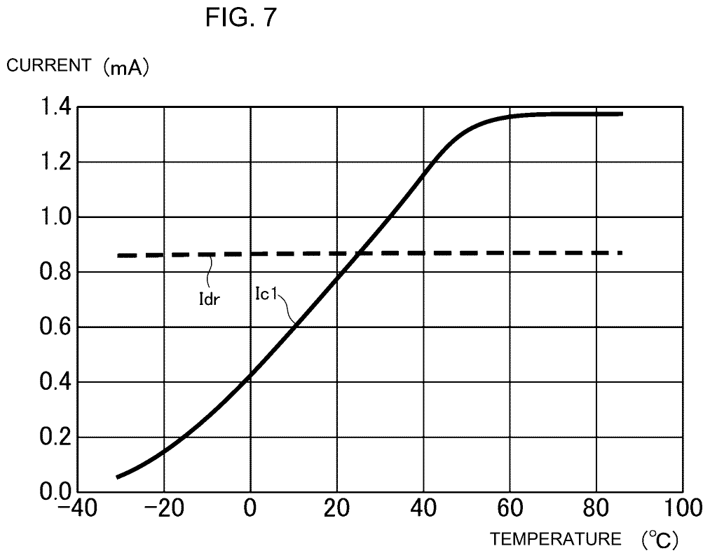

FIG. 7 is a graph illustrating an example of the simulation results of temperature changes in the collector current Ic1 in the power amplifier circuit 105 and the diode current Idr in the power amplifier circuit 901. The vertical axis represents current with units of mA. The horizontal axis represents temperature with units of ° C.

As illustrated in FIG. 7, in the power amplifier circuit 901, the diode current Idr is substantially constant relative to temperature. In contrast, in the power amplifier circuit 105, the collector current Ic1 may be increased at high temperatures.

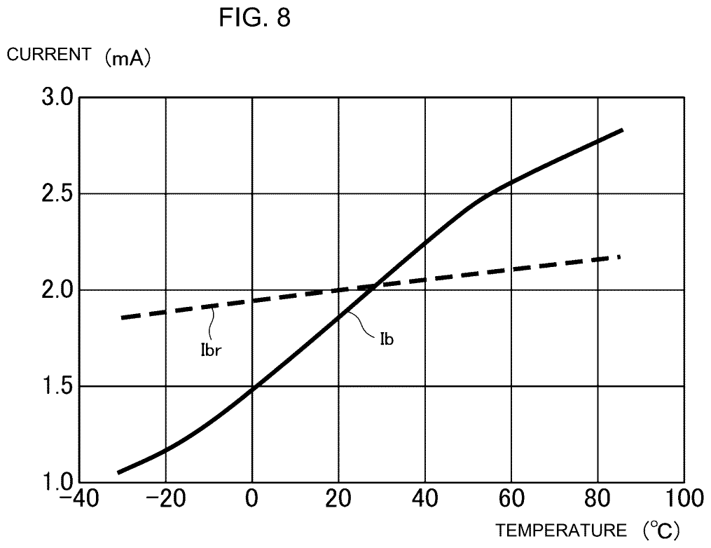

FIG. 8 is a graph illustrating an example of the simulation results of temperature changes in the bias current Ib in the power amplifier circuit 105 and the bias current Ibr in the power amplifier circuit 901. How FIG. 8 is seen is the same as that for FIG. 7.

As illustrated in FIG. 8, in the power amplifier circuit 901, the bias current Ibr is substantially constant relative to temperature. In contrast, in the power amplifier circuit 105, the bias current Ib may be increased at high temperatures.

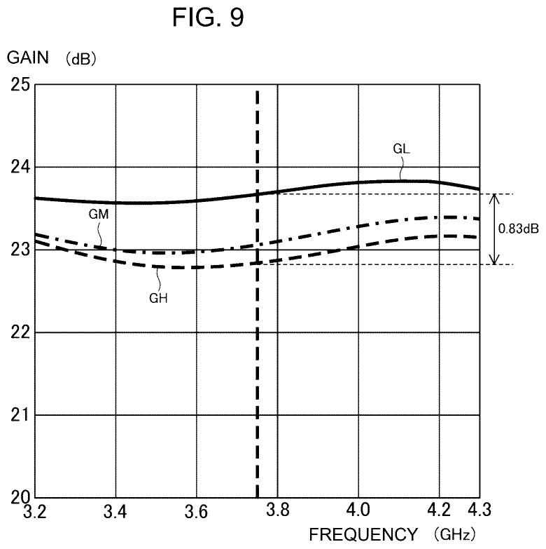

FIG. 9 is a graph illustrating an example of the simulation results of frequency changes in the gain of the amplifier 56 in the power amplifier circuit 105. The vertical axis represents gain in units of dB. The horizontal axis represents frequency in units of GHz.

As illustrated in FIG. 9, curves GL, GM, and GH each represent frequency changes in the gain of the amplifier 56 at a corresponding one of −30° C., 25° C., and 85° C.

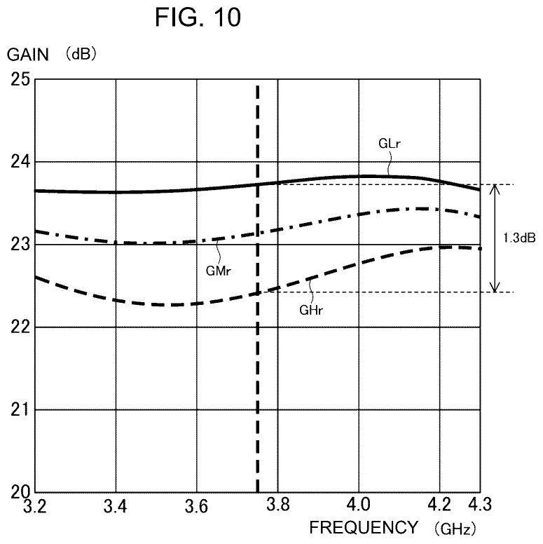

FIG. 10 is a graph illustrating an example of the simulation results of frequency changes in the gain of the amplifier 56 in the power amplifier circuit 901. How FIG. 10 is seen is the same as that for FIG. 9.

As illustrated in FIG. 10, curves GLr, GMr, and GHr each represent frequency changes in the gain of the amplifier 56 at a corresponding one of −30° C., 25° C., and 85° C.

For example, in the power amplifier circuit 901, a difference between a gain at −30° C. and a gain at 85° C. at the time of 3.75 GHz is 1.3 dB. In contrast, in the power amplifier circuit 105, the difference may be improved to 0.83 dB at the time of 3.75 GHZ. That is, in the power amplifier circuit 105, a decrease in the gain of the amplifier 56 in the high temperature may be prevented.

### Sixth Embodiment

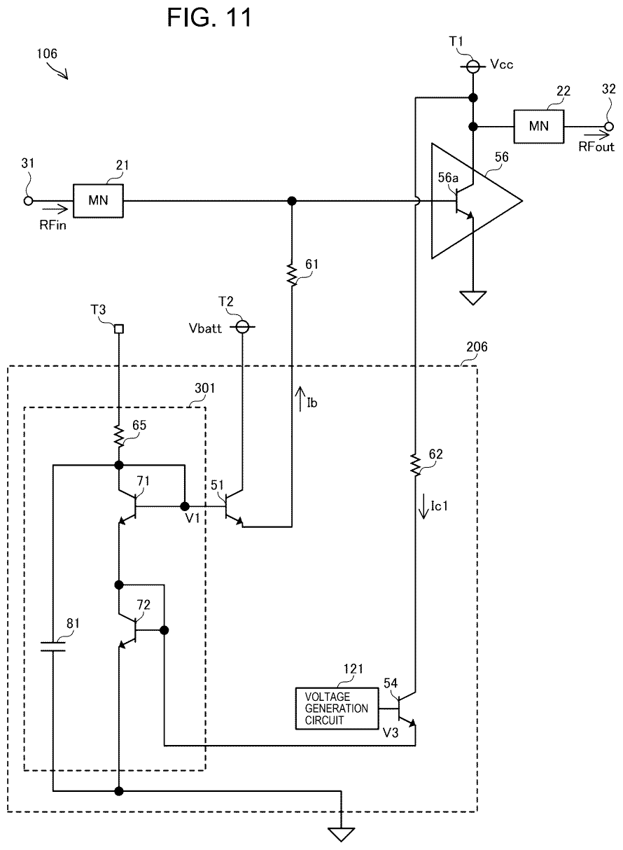

A power amplifier circuit according to a sixth embodiment will be described. FIG. 11 is a circuit diagram of a power amplifier circuit 106. As illustrated in FIG. 11, the power amplifier circuit 106 is different from the power amplifier circuit 101 according to the first embodiment in that the collector current Ic1 is blocked when the amplifier 56 transitions to the off state.

As compared with the power amplifier circuit 101 illustrated in FIG. 1, the power amplifier circuit 106 includes a bias circuit 206 in place of the bias circuit 201. As compared with the bias circuit 201 illustrated in FIG. 1, the bias circuit 206 includes a voltage generation circuit 121 and the transistor 54 in place of the constant-voltage generation circuit 111 and the transistor 52.

The transistor 54 has the collector connected to the voltage supply terminal T1 with the resistance element 62 interposed therebetween, the base, and the emitter connected to the collector of the transistor 72.

When a control signal causing the on state of the amplifier 56 is supplied from the control terminal T3, the voltage generation circuit 121 supplies the base of the transistor 54 with a voltage V3 causing the on state of the transistor 54.

In contrast, when a control signal causing the off state of the amplifier 56 is supplied from the control terminal T3, the voltage generation circuit 121 supplies the base of the transistor 54 with the voltage V3 causing the off state of the transistor 54.

The exemplary embodiments of the present disclosure have heretofore been described. In the power amplifier circuits 101 to 105, the amplifier 56 operates on power supplied from the voltage supply terminal T1. The bias supply transistor 51 has the collector supplied with power from the voltage supply terminal T2, the emitter that supplies the bias to the amplifier 56 via the resistance element 61, and the base connected to the control terminal T3. The transistor 71 has the collector, the base, and the emitter, the collector and the base being connected to the control terminal T3. The transistor 72 has the collector and the base that are connected to the emitter of the transistor 71 and the emitter connected to ground. The transistor 52 has the collector connected to the voltage supply terminal T1 with the resistance element 62 interposed therebetween, the base, and the emitter connected to the collector and the base of the transistor 72. The constant-voltage generation circuit 112 supplies the constant voltage V2 to the base of the transistor 52.

As described above, the gain of the amplifier 56 and the base-emitter voltage Vbe across the transistor 72 are decreased in response to a temperature increase; however, with the configuration in which the constant-voltage generation circuit 111 supplies the constant voltage V2 regardless of the temperature, the base-emitter voltage Vbe across the transistor 52 is increased, and thus the collector current Ic1 in the transistor 52 may be increased. The base current of the transistor 72 is thereby increased, and thus the current that flows to the transistors 71 and 72 may be increased. The bias current Ib supplied to the amplifier 56 by the bias supply transistor 51 current mirror connected to the transistor 71 is then increased, and thus the gain of the amplifier 56 may be increased. Accordingly, a change in the gain of an amplifier at a temperature increase may be appropriately compensated.

In the power amplifier circuit 102, the constant-voltage generation circuit 111 includes the resistance element 63 and the transistor 53. The resistance element 63 has the first end connected to the voltage supply terminal T2 and the second end connected to the base of the transistor 52. The transistor 53 has the collector connected to the second end of the resistance element 63, the emitter connected to ground, and the base connected to the base of the bias supply transistor 51.

As described above, with the simplified configuration of the one resistance element and the one transistor, the circuit that applies the constant voltage V2 to the base of the transistor 52 may be achieved. In addition, with the configuration in which the base of the transistor 53 is connected to the control terminal T3, the transistor 53 may be caused to transition to the off state when the control signal supplied from the control terminal T3 becomes off. The current that flows from the voltage supply terminal T2 to ground via the resistance element 63 and the transistor 53 may thereby be blocked when the amplifier 56 enters into the off state, and thus power consumption may be reduced.

In the power amplifier circuit 103, as compared with the constant-voltage generation circuit 111, the constant-voltage generation circuit 112 further includes the resistance element 64. The resistance element 64 is provided between the emitter of the transistor 53 and ground.

With the configuration as described above, the constant voltage V2 applied to the base of the transistor 52 may be appropriately controlled by appropriately setting the temperature characteristics of the transistor 53, the resistance value of the resistance element 63, and the resistance value of the resistance element 64. Specifically, for example, the constant voltage V2 at a high temperature may be slightly increased or decreased.

As compared with the power amplifier circuit 101, the power amplifier circuit 104 further includes the transistor 54. The transistor 54 has the collector connected to the emitter of the transistor 52, the base connected to the control terminal T3, and the emitter connected to the collector and the base of the transistor 72.

As described above, with the configuration in which the base of the transistor 54 is connected to the control terminal T3, the transistor 54 may be caused to transition to the off state when the control signal supplied from the control terminal T3 becomes off. The current that flows from the voltage supply terminal T1 to ground via the resistance element 62, the transistor 52, the transistor 54, and the transistor 72 may thereby be blocked when the amplifier 56 enters into the off state, and thus power consumption may be reduced.

In the power amplifier circuit 106, the amplifier 56 operates on power supplied from the voltage supply terminal T1. The bias supply transistor 51 has the collector supplied with power from the voltage supply terminal T2, the emitter that supplies the bias to the amplifier 56 via the resistance element 61, and the base connected to the control terminal T3. The transistor 71 has the collector, the base, and the emitter, the collector and the base being connected to the control terminal T3. The transistor 72 has the collector and the base that are connected to the emitter of the transistor 71 and the emitter connected to ground. The transistor 54 has the collector connected to the voltage supply terminal T1 with the resistance element 62 interposed therebetween, the base, and the emitter connected to the collector and the base of the transistor 72. When the control signal causing the on state of the amplifier 56 is supplied from the control terminal T3, the voltage generation circuit 121 supplies the base of the transistor 54 with the voltage V3 causing the on state of the transistor 54. When the control signal causing the off state of the amplifier 56 is supplied from the control terminal T3, the voltage generation circuit 121 supplies the base of the transistor 54 with the voltage V3 causing the off state of the transistor 54.

As described above, with the configuration in which the voltage V3 is supplied to the base of the transistor 54, the transistor 54 may be caused to transition to the off state when the control signal causing the off state of the amplifier 56 is supplied from the control terminal T3. The current that flows from the voltage supply terminal T1 to ground via the resistance element 62, the transistor 54, and the transistor 72 may thereby be blocked when the amplifier 56 enters into the off state, and thus power consumption may be reduced.

In the power amplifier circuits 101 to 106, the transistor 72 is thermally coupled to the amplifier 56.

With the configuration as described above, even if the temperature of the amplifier 56 is changed, the temperature of the transistor 72 may be made substantially the same as the temperature of the amplifier 56, and thus a gain change in the amplifier 56 at a temperature change may be compensated quickly.

The embodiments described above have been provided for easier understanding of the present disclosure and are not intended to limit the interpretation of the present disclosure. The present disclosure may be changed/improved without departing from the spirit thereof and includes its equivalents. That is, any of the embodiments subjected to a designing change appropriately by those skilled in the art is included in the scope of the present disclosure as long as the changed embodiment has the feature of the present disclosure. For example, the components of each embodiment, the arrangement, the material, the condition, the shape, the size of each component are not limited to those exemplified and may be changed appropriately. It goes without saying that each embodiment is an example and the configuration described in the embodiment may be partially replaced or combined with that in a different one of the embodiments. These are included in the scope of the present disclosure, as long as these have the feature of the present disclosure.

<1> A power amplifier circuit includes: an amplifier that operates on power supplied from a first terminal; a first transistor having a collector or a drain, an emitter or a source, and a base or a gate, the collector or the drain being supplied with power from a second terminal, the emitter or the source supplying bias to the amplifier via a first resistance element, the base or the gate being connected to a control terminal; a first diode having an anode and a cathode, the anode being connected to the control terminal; a second diode having an anode and a cathode, the anode being connected to the cathode of the first diode, the cathode being connected to ground; a second transistor having a collector or a drain, a base or a gate, and an emitter or a source, the collector or the drain being connected to the first terminal with a second resistance element interposed between the first terminal and the collector or the drain, the emitter or the source being connected to the anode of the second diode; and a constant-voltage generation circuit that supplies a constant voltage to the base or the gate of the second transistor.

<2> In the power amplifier circuit according to <1>, the constant-voltage generation circuit includes a third resistance element having a first end connected to the second terminal and a second end connected to the base or the gate of the second transistor, and a third transistor having a collector or a drain, an emitter or a source, and a base or a gate, the collector or the drain being connected to the second end of the third resistance element, the emitter or the source being connected to the ground, the base or the gate being connected to the base or the gate of the first transistor.

<3> In the power amplifier circuit according to <2>, the constant-voltage generation circuit further includes a fourth resistance element provided between the emitter or the source of the third transistor and the ground.

<4> The power amplifier circuit according to any one of <1> to <3> further includes: a fourth transistor having a collector or a drain, a base or a gate, and an emitter or a source, the collector or the drain being connected to the emitter or the source of the second transistor, the base or the gate being connected to the control terminal, the emitter or the source being connected to the anode of the second diode.

<5> A power amplifier circuit includes: an amplifier that operates on power supplied from a first terminal; a first transistor having a collector or a drain, an emitter or a source, and a base or a gate, the collector or the drain being supplied with power from a second terminal, the emitter or the source supplying bias to the amplifier via a first resistance element, the base or the gate being connected to a control terminal; a first diode having an anode and a cathode, the anode being connected to the control terminal; a second diode having an anode and a cathode, the anode being connected to the cathode of the first diode, the cathode being connected to ground; a fourth transistor having a collector or a drain, a base or a gate, and an emitter or a source, the collector or the drain being connected to the first terminal with a second resistance element interposed between the first terminal and the collector or the drain, the emitter or the source being connected to the anode of the second diode; and a voltage generation circuit that supplies the base or the gate of the fourth transistor with a voltage causing an on state of the fourth transistor and a voltage causing an off state of the fourth transistor, the voltage causing the on state being supplied when a control signal causing an on state of the amplifier is supplied from the control terminal, the voltage causing the off state being supplied when a control signal causing an off state of the amplifier is supplied from the control terminal.

<6> In the power amplifier circuit according to any one of <1> to <5>, the second diode is thermally coupled to the amplifier.

What is claimed is:

1. A power amplifier circuit comprising:
an amplifier configured to operate on power supplied from a first terminal;
a first transistor having a collector or a drain, an emitter or a source, and a base or a gate, the collector or the drain of the first transistor being supplied with power from a second terminal, the emitter or the source of the first transistor being configured to supply a bias to the amplifier via a first resistance circuit element, the base or the gate of the first transistor being connected to a control terminal;
a first diode having an anode and a cathode, the anode of the first diode being connected to the control terminal;
a second diode having an anode and a cathode, the anode of the second diode being connected to the cathode of the first diode, the cathode of the second diode being connected to ground;
a second transistor having a collector or a drain, a base or a gate, and an emitter or a source, the collector or the drain of the second transistor being connected to the first terminal with a second resistance circuit element interposed between the first terminal and the collector or the drain of the second transistor, the emitter or the source of the second transistor being connected to the anode of the second diode; and
a constant-voltage generation circuit configured to supply a constant voltage to the base or the gate of the second transistor.

2. The power amplifier circuit according to claim 1, wherein the constant-voltage generation circuit comprises:
a third resistance circuit element having a first end connected to the second terminal and a second end connected to the base or the gate of the second transistor, and
a third transistor having a collector or a drain, an emitter or a source, and a base or a gate, the collector or the drain of the third transistor being connected to the second end of the third resistance circuit element, the emitter or the source of the third transistor being connected to ground, the base or the gate of the third transistor being connected to the base or the gate of the first transistor.

3. The power amplifier circuit according to claim 2, wherein the constant-voltage generation circuit further comprises:
a fourth resistance circuit element between the emitter or the source of the third transistor and ground.

4. The power amplifier circuit according to claim 1, further comprising:
a fourth transistor having a collector or a drain, a base or a gate, and an emitter or a source, the collector or the drain of the fourth transistor being connected to the emitter or the source of the second transistor, the base or the gate of the fourth transistor being connected to the control terminal, the emitter or the source of the fourth transistor being connected to the anode of the second diode.

5. The power amplifier circuit according to claim 2, further comprising:
a fourth transistor having a collector or a drain, a base or a gate, and an emitter or a source, the collector or the drain of the fourth transistor being connected to the emitter or the source of the second transistor, the base or the gate of the fourth transistor being connected to the control terminal, the emitter or the source of the fourth transistor being connected to the anode of the second diode.

6. The power amplifier circuit according to claim 3, further comprising:
a fourth transistor having a collector or a drain, a base or a gate, and an emitter or a source, the collector or the drain of the fourth transistor being connected to the emitter or the source of the second transistor, the base or the gate of the fourth transistor being connected to the control terminal, the emitter or the source of the fourth transistor being connected to the anode of the second diode.

7. A power amplifier circuit comprising:
an amplifier configured to operate on power supplied from a first terminal;
a first transistor having a collector or a drain, an emitter or a source, and a base or a gate, the collector or the drain of the first transistor being supplied with power from a second terminal, the emitter or the source of the first transistor being configured to supply a bias to the amplifier via a first resistance circuit element, the base or the gate of the first transistor being connected to a control terminal;
a first diode having an anode and a cathode, the anode of the first diode being connected to the control terminal;
a second diode having an anode and a cathode, the anode of the second diode being connected to the cathode of the first diode, the cathode of the second diode being connected to ground;
a fourth transistor having a collector or a drain, a base or a gate, and an emitter or a source, the collector or the drain of the fourth transistor being connected to the first terminal with a second resistance circuit element interposed between the first terminal and the collector or the drain of the fourth transistor, the emitter or the source of the fourth transistor being connected to the anode of the second diode; and
a voltage generation circuit configured to supply a voltage to the base or the gate of the fourth transistor,
wherein the voltage generation circuit is configured to supply the voltage at a level that causes the fourth transistor to be in an on state when a control signal causing an on state of the amplifier is supplied from the control terminal, and
wherein the voltage generation circuit is configured to supply the voltage at a level that causes the fourth transistor to be in in an off state when a control signal causing an off state of the amplifier is supplied from the control terminal.

8. The power amplifier circuit according to claim 1, wherein the second diode is thermally coupled to the amplifier.

9. The power amplifier circuit according to claim 7, wherein the second diode is thermally coupled to the amplifier.
